(19) United States
(12) Patent Application Publication
(10) Pub. No.: US 2006/0050902 A1
(43) Pub. Date: Mar. 9, 2006

(54) Portable audio playing device

(75) Inventor: Szu-Wei Sun, Taoyuan Shien (TW)

Correspondence Address: NIKOLAI & MERSEREAU, P.A., 900 SECOND AVENUE SOUTH, SUITE 820, MINNEAPOLIS, MN, 55402, US

(73) Assignee: Galax Multimedia Co., Ltd., Taoyuan Shien (TW)

(21) Appl. No.: 10/935,671

(22) Filed: Sep. 7, 2004

(51) Int. Cl. H03F 21/00; H04B 3/00

(52) U.S. Cl. 381/120; 381/77

(57) ABSTRACT

A portable audio playing device which is able to play music directly by low-power source or even without being connected to power supply such as USB. The device includes an out source DC force serially connected to a source selector with a Pre-Amp and a power system distribution and regulator. A power management block is connected between the out source DC force and the power system distribution and regulator. The power management block is connected to a battery charger, a battery cell and a DC converter charge pump which is connected to the power system distribution and regulator and the power stage or driver. The device proceeds charging steps during playing music and can also be used outdoor by gaining enough power to the source selector and the power stage or driver from the power management block.

### FIELD OF THE INVENTION

The present invention relates to an audio playing device with lower-power input and high-power output, especially for a design with inherent power supply which provides efficient power to the speakers and amplifiers so as to display music directly without being connected to high-power power supply.

### BACKGROUND OF THE INVENTION

Thanks for the modern technology, there are various types of audio playing devices in the market and these devices are made to involve multiple functions and to be compact so as to meet the requirements for playing with other playing platforms while obtaining the same features.

There are some problems for the power supply of the existed playing devices and this is inconvenient for the users. As shown in FIG. 1, the conventional playing device is serially connected to a power system distribution and regulation 15 to AC or DC 11, or battery unit 12 and a playing selection circuit 20 is connected to the power system distribution and regulation 15. The playing selection circuit 20 includes an Pre-Amp circuit 25 and the Pre-Amp circuit 25 and the power system distribution and regulation 15 are connected to a power stage or driver 30 in series. By the power stage or driver 30, the input signals can be played via the speakers 40. However, the speakers 40 have to be connected with the adapter all the time which provides electricity to the speakers 40. This restricts the mobility of the playing device and low-power power supply cannot drive the speakers.

The present invention intends to provide a playing device wherein the energy can be transferred to the device within a period of time and the playing device may play the music with high-power output and low-power input. The device has better mobility and is compact for convenience of being carried.

### SUMMARY OF THE INVENTION

The present invention relates to a portable playing device which is convenient to be carried and improves functions of the device and the quality of living.

The present invention is a portable audio playing device that comprises an out source DC force serially connected to a source selector via a power system distribution and regulator. The source selector includes a Pre-Amp which is connected to a power stage or driver and the power stage or driver is connected to speakers. The out source DC force is connected to a battery charger which includes a battery cell which is connected to a DC converter charge pump. The DC converter charge pump is connected to the power system distribution and regulator and the power stage or driver. The battery charger and the DC converter charge pump provide power to the power stage or driver to transfer low-power input into high-power output via the speakers.

The device is proceeding charging steps during playing music and can also be used outdoor by gaining enough power to the source selector and the power stage or driver from the power management block.

The present invention will become more obvious from the following description when taken in connection with the accompanying drawings which show, for purposes of illustration only, a preferred embodiment in accordance with the present invention.

### BRIEF DESCRIPTION OF THE DRAWINGS

FIG. 1 shows a block diagram of a conventional audio playing device, and

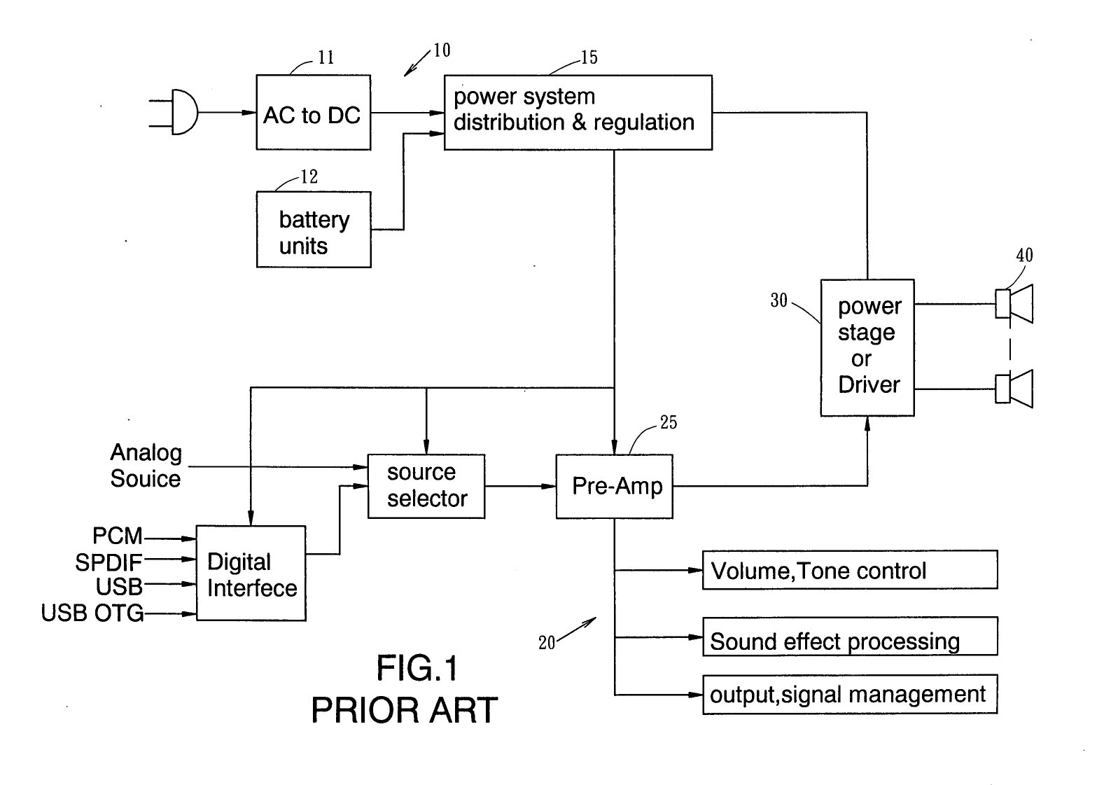

FIG. 2 shows a block diagram of a portable audio playing device of the present invention.

### DETAILED DESCRIPTION OF THE PREFERRED EMBODIMENT

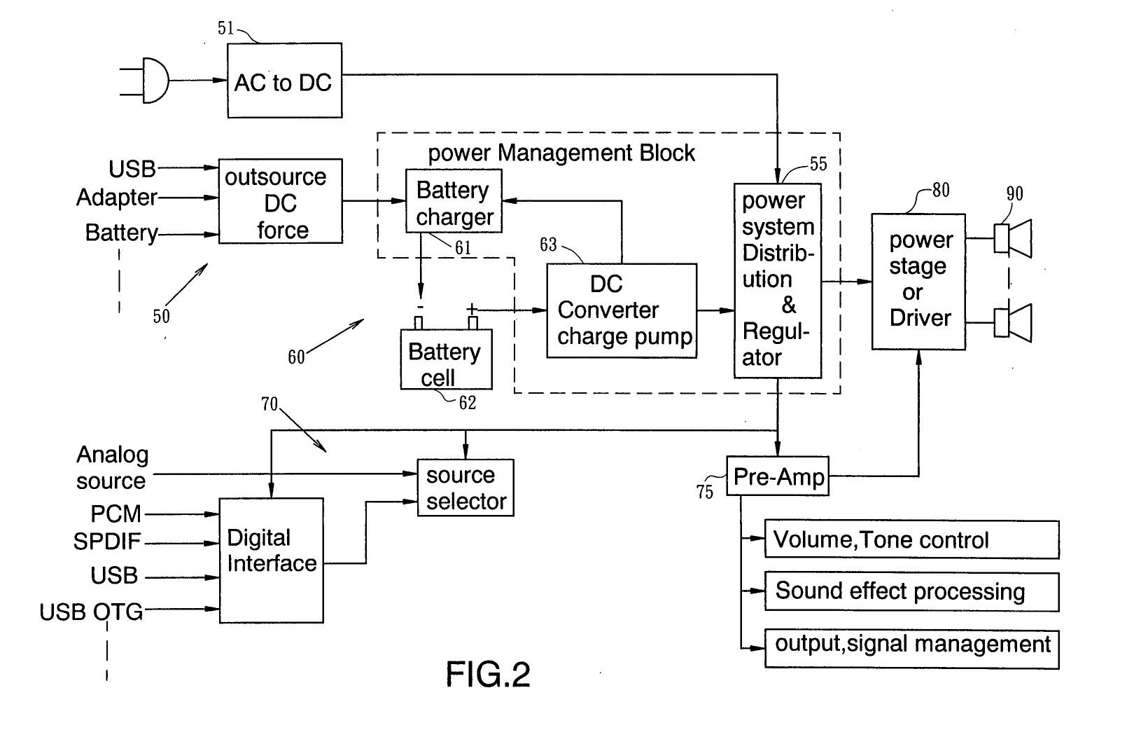

Referring to FIG. 2, the portable audio playing device of the present invention comprises an out source DC force 50 or an adapter 51 which is serially connected to a source selector 70 via a power system distribution and regulator 55. The source selector 70 can accept different types of input and output signals and includes a Pre-Amp 75 which is connected to the power system distribution and regulator 55. The Pre-Amp 75 is connected in serial to a power stage or driver 80 which is connected to multiple speakers 90. The arrangement mentioned above is well known in the art and will not be described in detail.

A power management block 60 is connected between the out source DC force 50 and the source selector 70, and a battery charger 61 with a battery cell 62 are connected to the power management block 60 and the battery cell 62 is connected to a DC converter charge pump 63 which is connected to the power system distribution and regulator 55 and the power stage or driver 80. The power system distribution and regulator 55 and the Pre-Amp 75 of the source selector 70 are connected with each other.

The power management block 60 provides power to the source selector 70 and the power stage or driver 80 so as to obtain a low-power input with large-power output device which is played via speakers directly.

When operation the device of the present invention, if adapter or USB is used to provide power to the out source DC force 50, the electric current is connected to the source selector 70 and the power stage or driver 80 via the power management block 60. If speakers 90 are connected to the power stage or driver 80, the music can be played via the speakers 90, and in the meanwhile, the spare electric current is stored in the battery cell 62 via the battery charger 61.

When the device is used outdoor, the battery cell 62 of the power management block 60 provides power to the power stage or driver 80 which is connected to the speakers 90 to play music directly without extra power supplies.

The device can also be connected with low-power input such as by USB, the battery charger 61 of the power management block 60, the battery cell 62 and the DC converter charge pump 63 provide power to the power stage or driver 80 which is connected to the speakers 90 to play music directly without extra power supplies.

While we have shown and described the embodiment in accordance with the present invention, it should be clear to those skilled in the art that further embodiments may be made without departing from the scope of the present invention.

What is claimed is:

1. A portable audio playing device comprising:
an out source DC force serially connected to a source selector via a power system distribution and regulator, the source selector including a Pre-Amp which is connected to a power stage or driver, the power stage or driver connected to speakers, the out source DC force connected to a battery charger which includes a battery cell which is connected to a DC converter charge pump, DC converter charge pump connected to the power system distribution and regulator and the power stage or driver, the battery charger and the DC converter charge pump providing power to the power stage or driver to transfer low-power input into high-power output via the speakers.
